(19) United States
(12) Patent Application Publication
(10) Pub. No.: US 2014/0230170 A1
(43) Pub. Date: Aug. 21, 2014

(54) POST-CMP CLEANING APPARATUS AND METHOD

(71) Applicant: ENTEGRIS, INC., Billerica, MA (US)

(72) Inventor: Chintan Patel, Billerica, MA (US)

(21) Appl. No.: 14/347,170

(22) PCT Filed: Sep. 26, 2012
(86) PCT No.: PCT/US2012/057337

§ 371 Date: Mar. 25, 2014

Related U.S. Application Data
(60) Provisional application No. 61/539,342, filed on Sep. 26, 2011.

(51) Int. Cl. H01L 21/67

(52) U.S. Cl. CPC H01L 21/67046
USPC 15/88.4

(57) ABSTRACT

A brush for cleaning of substrates such as for post chemical mechanical polishing (post-CMP) of the substrates, utilizes asymmetrical nodules or nodules with varying spacing, size, features, densities to provide an improved cleaning of substrates.

### RELATED APPLICATIONS

This present application is a National Phase entry of PCT Application No. PCT/US2012/057337, filed Sep. 26, 2012, which claims priority to U.S. Provisional Application No. 61/539,342 filed Sep. 26, 2011, the disclosure of which are incorporated by reference in their entirety.

### FIELD OF THE INVENTION

The present invention is generally directed to chemical mechanical polishing of substrates. More specifically, the present invention is directed to a brush for cleaning substrates following chemical mechanical polishing.

### BACKGROUND OF THE INVENTION

Integrated circuits can be formed on semiconductor substrates, particularly silicon wafers, by the sequential deposition of conductive, semiconductive and insulative layers on the wafer. Circuitry features can be etched on after each layer is deposited. After a series of layers have been deposited and etched, the uppermost surface of the substrate can become increasingly non-planar. Non-planar surfaces can cause problems in the photolithographic steps of the integrated circuit fabrication process. As such, it is necessary to periodically planarize the semiconductor substrate surface.

Damascene is a process in which interconnecting metal lines are formed by isolating dielectrics. In damascening, an interconnecting pattern is first lithographically defined in the layer of dielectric, and then metal is deposited to fill in the resulting trenches. Excess metal can be removed by chemical-mechanical polishing (planarization). Chemical-mechanical polishing (CMP), also called chemical-mechanical planarization, refers to a method of removing layers of solid through chemical-mechanical polishing carried out for the purpose of surface planarization and definition of the metal interconnecting pattern. Dual damascene is a modified version of the damascene process that is used to form metal interconnecting geometry using a CMP process instead of metal etching. In dual damascene, two interlayer dielectric patterning steps and one CMP step create a pattern that would otherwise require two patterning steps and two metal CMP steps when using a conventional damascene process.

In a typical CMP operation, a rotating polishing pad, which receives a chemically reactive slurry, is used to polish the outermost surface of the substrate. The substrate is positioned over the polishing pad and is held in place by a retaining ring. Typically the substrate and retaining ring are mounted on a carrier or polishing head. A controlled force is exerted on the substrate by the carrier head to press the substrate against the polishing pad. The movement of the polishing pad across the surface of the substrate causes material to be chemically and mechanically removed from the face of the substrate.

After polishing, slurry residue conventionally is cleaned or scrubbed from substrate surface via a scrubbing device such as a brush. U.S. Pat. No. 4,566,911 discloses a cleaning brush roller with a gear-like configuration having many parallel grooves formed at an angle to the roll axis of 0 degrees to 90 degrees and also discloses projections of a circular, ellipsoidal, rectangular, or diamond shape or the like and having a total surface area of the projections of 15% to 65% of the whole surface area. Post-CMP cleaning brushes may be formed of foam. Fluid can be injected outwardly through the foam roller brush as the roller is rotating and in engagement with the substrate during the cleaning process to clean particle contaminants off of the substrates.

Such brushes are typically comprised of polyvinyl alcohol. A certain level of mechanical force must be applied in order to remove the particles as the brushes are rotated and slurry is supplied to the substrate surface. However, such substrates are fragile and if the mechanical force is too great, it can result in scratches or other damage to the substrates. It would therefore be desirable to provide post-CMP polishing apparatuses that optimize the amount of force needed to clean substrates while reducing the possibility of having excessive forces that will damage the substrates, in effect normalizing the forces.

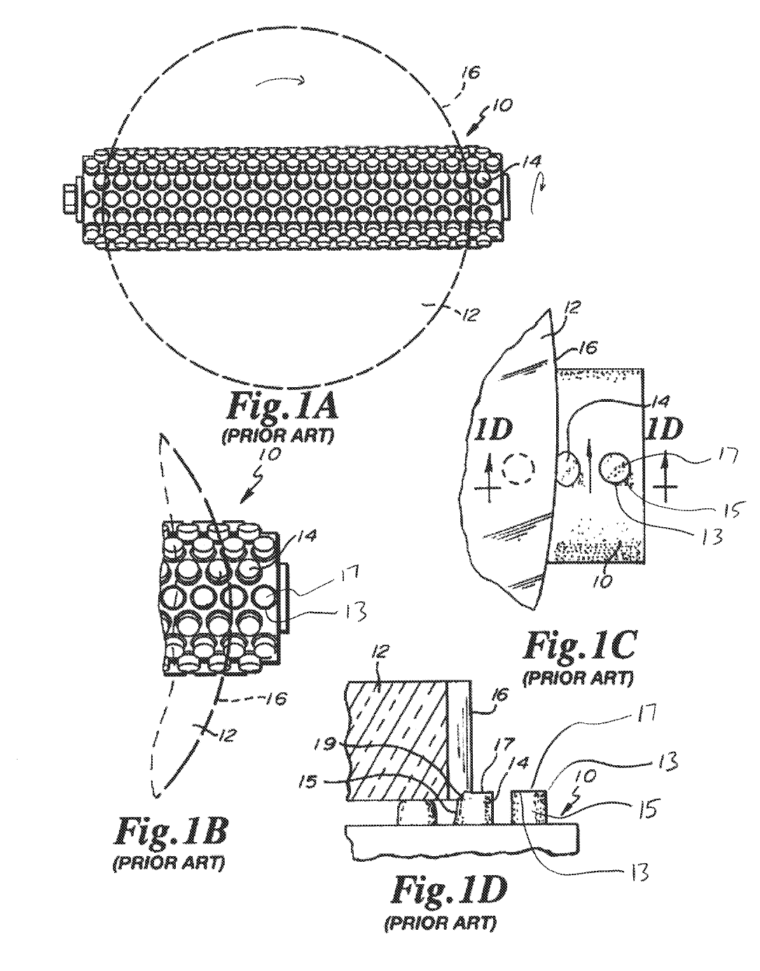

FIGS. 1A-1D depict a prior art post-CMP cleaning brush 10 that can be referred to as a standard brush. Brush 10 includes identical cleaning nodules 14 along the entire length of brush, so that both a central portion of a substrate 12 and an edge portion of the substrate 12 are cleaned with nodules of the same shape. As can be seen in FIGS. 1B, 1C and 1D, in use such brushes 10 can lead to only a portion of nodules 14 contacting the outer edge 16 of the substrate 12. Referring to FIG. 1D, the substrate 12 contacts a corner 19 of a nodule 14 where a side surface 15 and a top or outer surface 17 of the nodule 14 meet. Such partial edge contact between nodules and the substrate edge 16 can cause nodules 14 to deform or break during use and can result in incomplete or non-uniform cleaning of the substrate's end regions as well as damage to the substrate. Flat top surface 17 of nodules 14 meets side surfaces 15 at right angles to form sharp edges 13 that extend around the top surface 17 of the nodules 14. Thus, as the brush 10 is rotated and rows of nodules 14 sequentially come into contact with the substrate 12, the first portion of the nodules 14 that contacts the substrate 12 is the sharp right-angle edges 13. The contact between these sharp edges 13 and the substrate 12 can lead to excessive force being applied to the substrate and therefore damage the substrate 12. Moreover, contact with a corner of a nodule that then transitions to full contact with the nodule can cause folding or otherwise non uniform compressing of the nodule which may not perform optimally. Also, it is understood that such initial corner contact can cause excessive wear on the corner reducing the useful life of the brush.

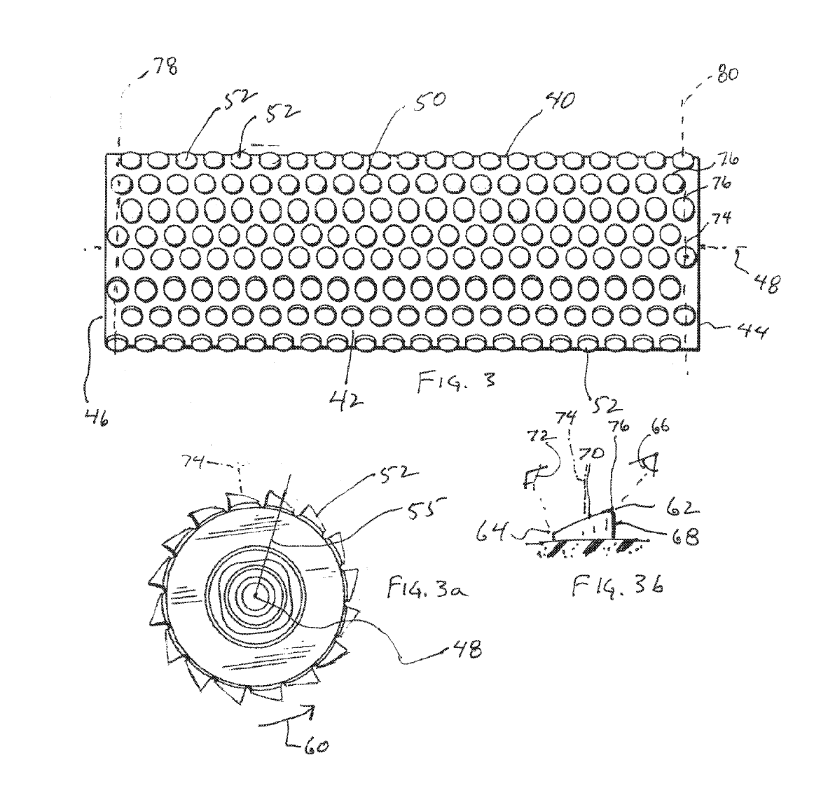

In addition to the brush contact at the edge of the substrate, the characteristics of the brush/substrate engagement will vary within the substrate varying with the position of the brush/substrate interface. Moreover, as best illustrated in Prior Art FIGS. 1A and 3, the cylindrical brushes rotate as the substrate is rotating and the cylindrical brush extends along a diameter, a radius, or a chord of the circular footprint of the substrate. The brush substrate contact is typically with the nodules and within a region that may be designated as a contact strip with a width significantly less than the diameter of the brush. Of course, the entire “strip” is not in engagement with the substrate at any moment, only the nodules located in the strip. Additionally the strip is constantly moving on the substrate in that the substrate is rotating. The strip where it crosses the rotational center of the substrate will effectively maintain contact continuously with the substrate, that is nodules within the strip will enter and exit the strip (due to rotation of the brush) but the strip will never leave the center of the substrate. At the edges of the substrate the strip will be engaged at any particular region momentarily as the substrate rotates. Correspondingly, the brush/substrate contact per unit area of the substrate will be at the maximum at the center of the substrate and, to the extent the nodules are uniformly shaped and arranged as in FIG. 1a, the brush/substrate contact per unit area of the substrate will decrease along the strip towards the substrate edge.

Conventionally, as to the engagement of the nodules with the substrate, it is initially the leading corner or “plateau” edge that makes contact, then the contact transitions to most of plateau surface and then transitions again to the trailing edge when the contact with the substrate ends. As the brush rotates, the stage from initial contact of a nodule to a “normal position”, when the nodule is positioned in a perpendicular orientation to the substrate, also where the substrate is in a tangential orientation to the brush, the brush nodule is being compressed. From the normal position to the disengagement position, the nodule is in a decompression mode, that is, it is expanding radially outward.

Additionally, the characteristics of the brush/nodule/substrate engagement will vary due to the position of the brush/substrate interface on the substrate. For example, due to the differing velocities of points or portions on the substrate, depending on the distance from the rotational center of the substrate, the time of contact with the brush and the relative velocity of portions of the substrate near substrate center with respect to the brush will vary compared to the relative velocity of portions of the substrate further away from the center of the substrate. Differing relative velocities can result in differing material removal rates or characteristics. Also, for example, in that the brush provides a contact region that is effectively the strip with a width extending across the substrate, as discussed above, particular regions of the substrate close to the center will be in engagement with the strip for more time (per revolution or per process interval) than regions farther away from the center. These differing engagement characteristics have not heretobefore been addressed or adequately addressed.

It is, of course, desirable to uniformly and optimally remove material from the substrate during CMP operations. It would be advantageous to provide a brush to accommodate or compensate for the differing brush/substrate interface characteristics that exist across the substrate as well as optimize the shape to take advantage of the stages of contact of the individual nodules with substrate and the associated compression and decompression of the nodules.

### SUMMARY OF THE INVENTION

The present invention is a post-CMP cleaning brush that can be used to clean various substrates such as semiconductor wafers, hard disks, flat panels and the like. The post-CMP brush has a plurality of nodules arranged that protrude outwardly from a cylindrical base portion and extend circumferentially around the brush. The nodules can have an asymmetric configuration that includes a leading edge of a substrate engagement surface of the nodules that is different from a trailing edge and is curved or rounded. Nodules can be positioned, shaped, and/or arranged such that they are adapted for their respective engagement position on the substrate (for example, distance from the center or distance from substrate edge) in order to provide optimal cleaning performance. The positioning, shaping, and/or arrangement of the nodules can vary continuously from the center of the substrate to the exterior edge or can have a plurality of groupings, for example three groupings of nodules with the members of each group having the same positioning, shape, and/or arrangement, and the groups varying from where the brush would engage the center of the substrate (typically the center of the cylindrical brush) to where the brush would engage the outer region of the substrate (typically the outer edge of the brush). For example, the size of the nodules on the brush that engage the lesser velocity center of the wafer could be larger, of greater contacting surface area, than the nodules that contact outer portions of the wafer that has greater velocity. This normalizes the relative amount of scrubbing that all portions of the wafer have, which is the amount of brush to wafer engagement time for each portion of the wafer.

Another example, the shape of the nodules may vary depending on their location on the brush, since the nodule wafer contact at the edges of the wafer will be at a higher relative velocity than towards the middle of the wafer, the nodules towards the middle may be more aggressively shaped to increase scrubbing action. The “more aggressive” shape may constitute different shapes such as wider leading edges or the nodules extending outwardly radially farther from the base portion of the sponge or the variation in the taper of the nodules.

Moreover, the nodules may, based on their position on the brush which correlates to the position on the substrate, have a variation in the distance they extend radially.

The nodules may have, when viewed in an axial direction (with respect to the axis of cylindrical brush), have a edge or corner and a trailing edge or corner with a surface therebetween, the surface may be substantially flat or have a convex curvature. In embodiments the leading corner is closer to the cylindrical base portion than the trailing corner. In embodiments, the trailing corner extends radially outwardly further than the leading corner. In embodiments, the distance between the trailing corner and the cylindrical portion, as measured along the nodule, is greater than the distance between the leading corner and the cylindrical base portion as measured along the nodule. In embodiments of the invention, the surface between the corners may be configured such that said surface contacts the substrate first as the brush is rotated as compared to the leading corner in conventional cylindrical nodules. In embodiments, said surface between the leading corner and trailing corner may be substantially flat and angled such that substantially all of the surface between the leading corner and trailing corner engages simultaneously. This provides more nodule surface area contact during the compression portion of the engagement cycle which is believed to provide enhanced cleaning. Moreover, during the decompression, separation of contact between the nodule and the substrate occurs quicker.

In embodiments of the invention nodules on cylindrical brushes are configured and the brush and substrate engagement arranged such that the nodule contact with the substrate is optimized and enhanced with respect to cleaning the substrate.

In an embodiment of the invention nodules on cylindrical brushes are configured and the brush and substrate engagement arranged such that the nodule contact with the substrate is enhanced during the compression arc.

In an embodiment of the invention nodules on cylindrical brushes are configured and the brush and substrate engagement arranged such that the nodule contact with the substrate is increased during the compression arc compared to conventional cylindrical nodules. In an embodiment of the invention nodules on cylindrical brushes are configured and the brush and substrate engagement arranged such that the nodule contact with the substrate is decreased during the compression arc compared to conventional cylindrical nodules.

Another embodiment of the invention is a method of post CMP cleaning of a surface of a semiconductor wafer or other substrate. The method includes engaging the surface of a rotating substrate with a rotating cylindrical foam roller having a plurality of nodules. Nodules may be arranged in axial rows extending circumferentially around the brush and can have an asymmetric configuration including a leading edge of a substrate engagement surface that is curved or rounded. In some embodiments, a pair of roller brushes can engage the substrate with a first brush engaging a top side of the substrate and a second brush engaging a bottom side of the substrate. In such embodiments, the brushes can rotate in opposite directions in order to meet each side of the rotating substrate. Thus, the substrate engagement surface of the asymmetric nodules of the first brush can be on the opposite side of the substrate engagement surface of the nodules of the second brush. The brush on the top side can be differently configured than the brush on the bottom side, that is, the nodules of the brush engaging the top surface of the substrate may be differently shaped, positioned, and/or arranged from the nodules of the brush engaging the bottom side.

Another feature and advantage of embodiments of the present invention is a brush having nodules with a smaller substrate contact area in the central region of the brush than nodules at edge regions of the brush. This provides a more even amount of contact between the nodules and the substrate at the center region of the substrate, which has more time duration of contact with the brush, than at the edge regions due to the smaller surface area per revolution of the substrate close to the center as compared to the farther from the center. This optimizes cleaning of the edge regions of the substrate while minimizing the possibility of damage to the central region due to excessive contact with the brush.

In embodiment, a post-CMP cleaning brush is configured to accommodate the differing velocities that exist along a radius of a rotating substrate. In embodiments, the brush can have differently configured nodules at edge regions along the length of the brush that will contact the faster moving portions of the substrate as compared to a central region of the brush that will engage a slower moving portion of the substrate corresponding to the middle portion of the substrate. Brush can include nodules having smaller substrate contact areas in the central region, which contacts the substrate with greater frequency, than at the edge regions. Moreover the density of the nodules, that is number of nodules per unit of area on the cylindrical surface of the brush, can vary with respect to where (distance from center or the substrate edge) on the substrate the particular nodules will be engaging the substrate. For example, a greater density for the portions of the sponge that will engage the center of the wafer. Additionally, the amount of surface area of engagement per unit of area on the cylindrical surface of the brush can vary dependent upon the position (distance measured from the center of the substrate or the substrate edge) on the substrate. For example, more surface area of engagement towards the center of the wafer may be advantageous.

A feature and advantage of embodiments of the present invention is the provision of nodules having a rounded substrate engagement surface that is the first portion of the nodule to engage the substrate such as a substrate as the brush is rotated. Rounded substrate engagement surfaces apply a more distributed force to substrates than right angle or “sharp” engagement surfaces and therefore reduce the possibility of damage to the substrates from contact with nodules.

Another feature and advantage of embodiments of the present invention is that asymmetric nodules allow for thinner nodules with curved engagement surfaces to be provided. Thinner nodules deform more easily upon contact with substrates and therefore less force is imparted on the substrates. As such, substrates are less likely to be damaged by nodules.

A further feature and advantage of embodiments of the present invention are asymmetric nodules having a stepped rear surface. Stepped rear surface allows the nodule to have a thinner engagement portion while having a thicker base portion. The nodules can therefore deform more easily when engaging a substrate, but the base portion provides a stronger base to prevent it from deforming too easily.

Asymmetrical arrangements, for example stepped arrangements may provide for a more uniform engagement force with the substrate by, for example, allowing a controlled folding of the most elevated portion of a nodule, in embodiments the nodule can fold to then seat on a further shoulder of the nodule or on the cylindrical surface of the brush.

In certain applications, it may be advantageous to provide multiple edge engagement by nodules which for certain slurry cleaning may operate more efficiently, in such cases, asymmetrical nodules may be configured to present more than one edge into engagement with the substrate as the nodule is rotated past the substrate. Such a nodule may have dual peaks.

### BRIEF DESCRIPTION

FIG. 1A is an illustration of a prior art post-CMP cleaning brush and a substrate (dashed circle);

FIG. 1B is a partial view of an edge portion of the brush and the substrate of FIG. 1A;

FIG. 1C is a partial view of an edge portion of the brush and the substrate of FIG. 1A;

FIG. 1D is a partial view of an edge portion of the brush and the substrate of FIG. 1A;

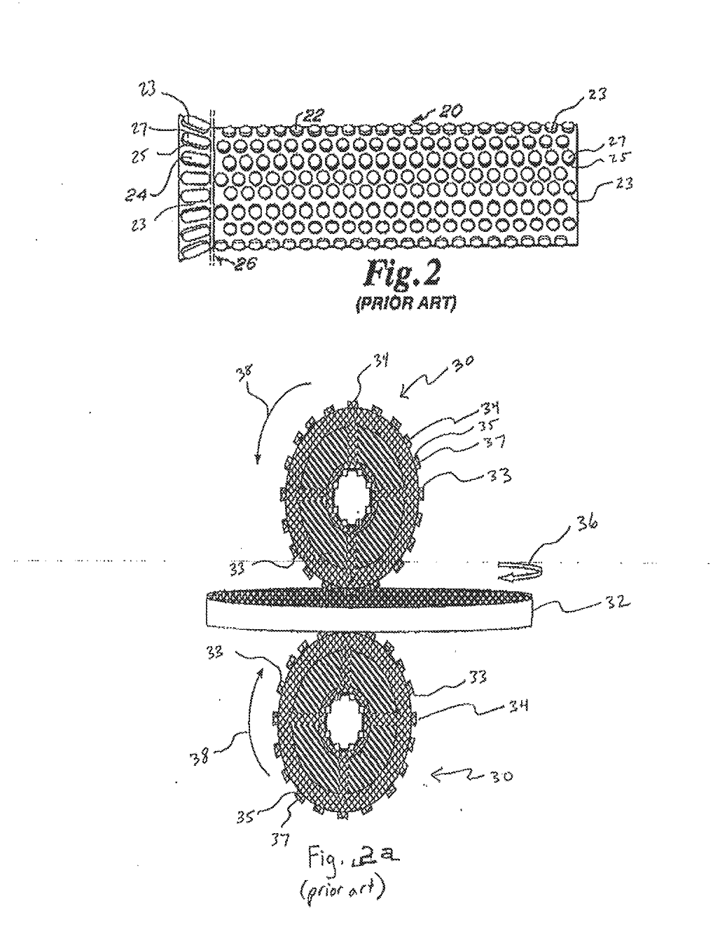

FIG. 2 is another post-CMP cleaning brush from the prior art;

FIG. 2a is a schematic cross sectional view of the brushes in a post-CMP cleaning process of the prior art;

FIG. 3 is a front view of a brush according to an embodiment of the invention;

FIG. 3a is a side elevational view of the brush of FIG. 3;

FIG. 3b is a detailed view of a nodule of the brush of FIGS. 3 and 3a;

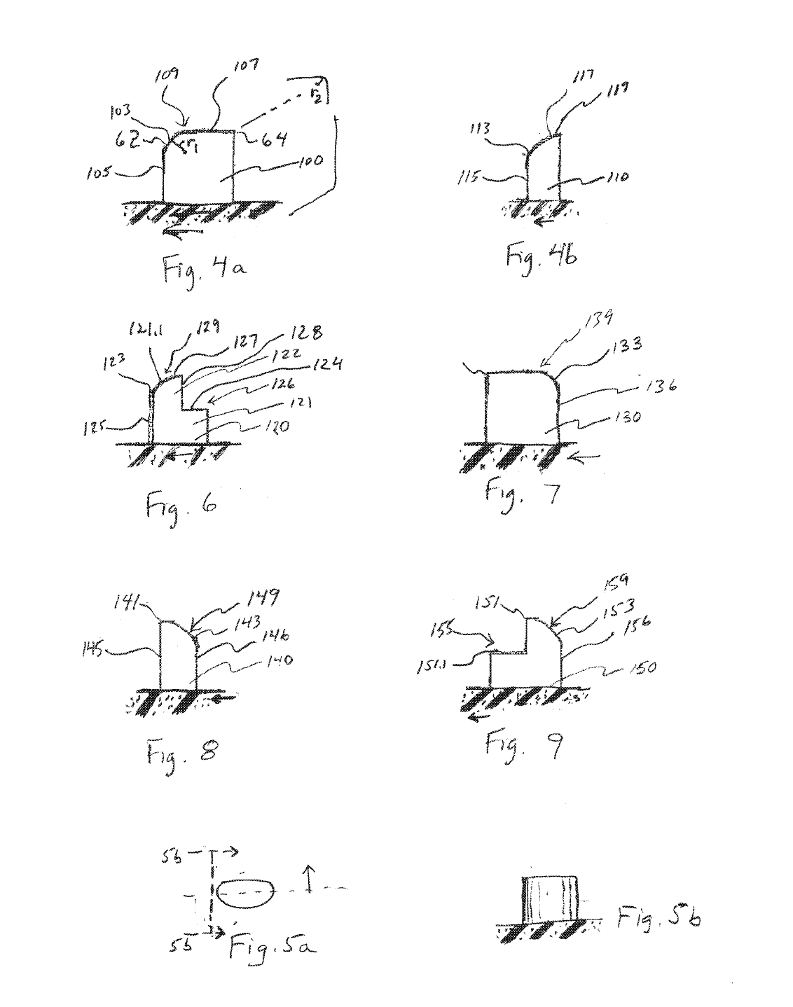

FIGS. 4a and 4b are side elevational views of asymmetrical nodules according to embodiments of the invention; the nodules are asymmetrical about a vertical plane normal to the page; on the cylindrical brush this translates to a plane through the axis of the cylindrical brush and through the nodule; these nodules may have cylindrical or ellipsoidal bases below the top structure;

FIG. 5a is a top plan view of an asymmetrical nodule that has a radius of curvature one side greater than that on the other; the dashed line through the nodule representing a plane extending through the axis of the cylindrical brush and the plane about which the nodule is asymmetrical, the arrow from the dashed line indicating an exemplary direction of rotation;

FIG. 5b is a side elevational view of the nodule of FIG. 5a taken at line 5b-5b;

FIGS. 6-9 are side elevational views of asymmetrical nodules according to embodiments of the invention; the nodules are asymmetrical at least about a vertical plane normal to the page; on the cylindrical brush this translates to a plane through the axis of the cylindrical brush and through the nodule, the arrows indicating an exemplary direction of rotation of the cylindrical brush of which the respective nodules are part;

FIG. 10-12 are perspective views of asymmetrical nodules according to embodiments of the invention with a circular footprint providing a cylindrical base;

FIGS. 13-15 are perspective views of asymmetrical nodules according to embodiments of the invention having a rectangular footprint;

FIG. 16-19 are perspective views of asymmetrical nodules according to embodiments of the invention with a circular footprint, these footprints could also be ellipsoidal;

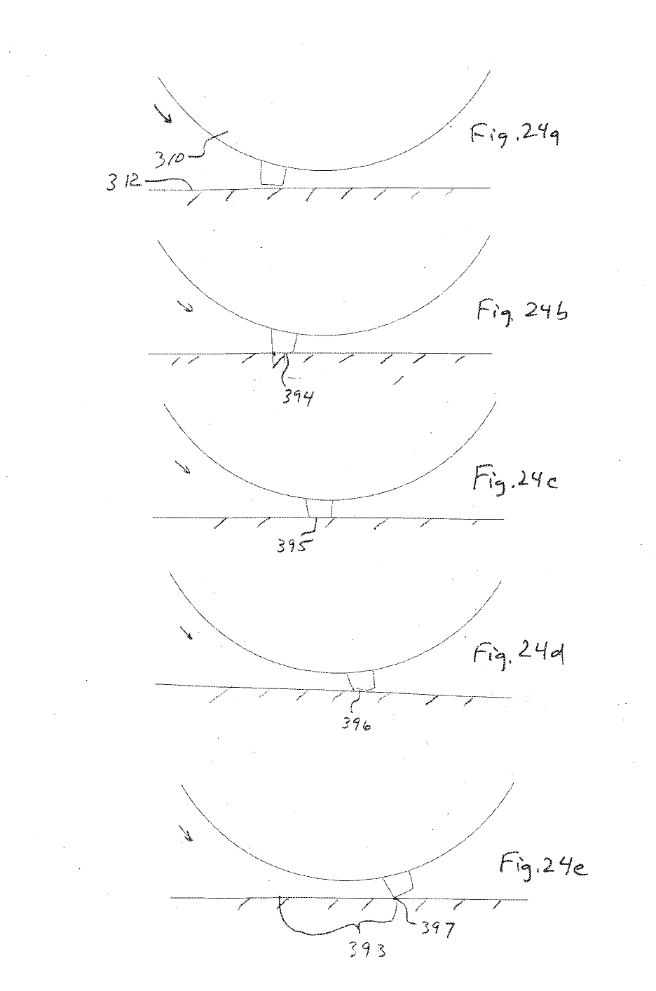

FIG. 20 is a post CMP cleaning process according to an embodiment of the invention;

FIG. 21 illustrates the nodule contact regions of a brush on a substrate according to an embodiment of the invention;

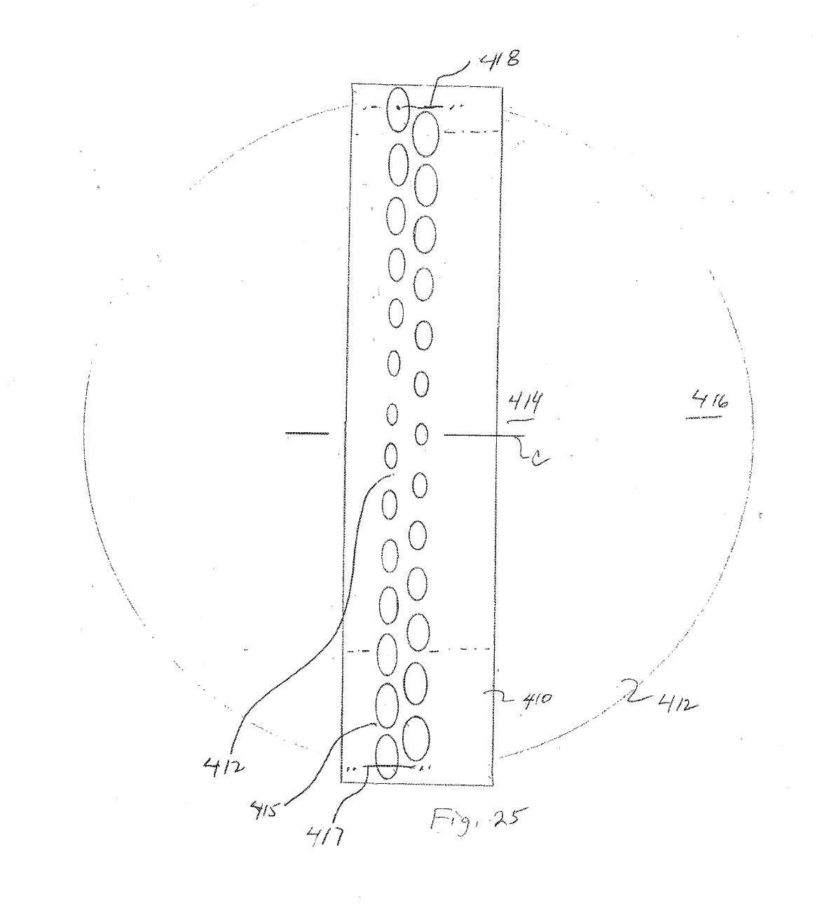

FIGS. 22a and 22b are schematic cross sectional views showing an asymmetrical nodule initialing engaging the substrate surface on the nodule's curved side;

FIGS. 23a and 23b are schematic cross sectional views showing an asymmetrical nodule initialing engaging the substrate surface on its curved side that fold over onto a shoulder of the nodule;

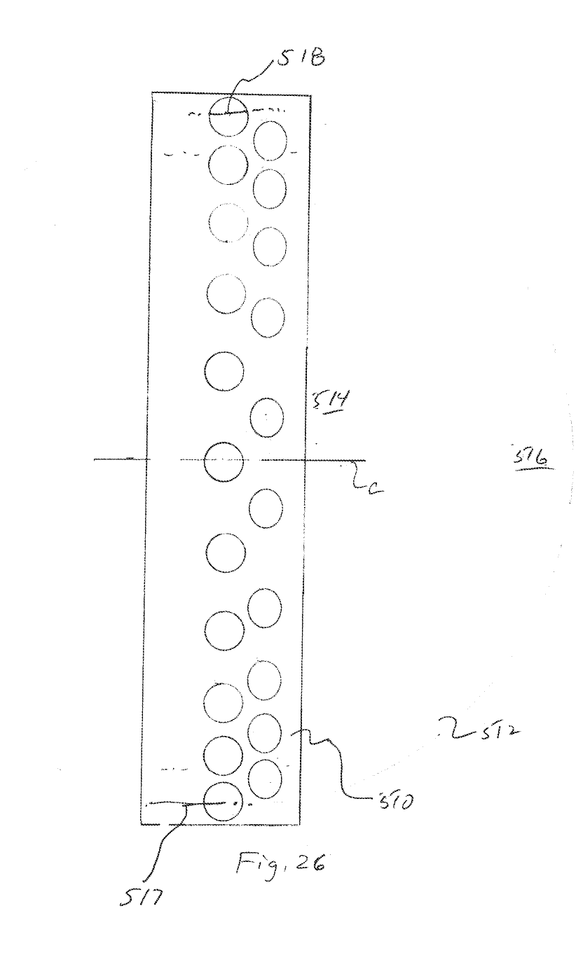

FIGS. 24a-24e are schematic cross sectional views showing an asymmetrical nodule initialing engaging the substrate surface on its curved side providing enhanced contact during the compression stage of substrate contact; and

FIG. 25 is a plan view of a brush over a substrate according to an embodiment of the invention where the nodule size is increased toward the edges of the substrate and the ends of the brush, for drawing simplicity, only two rows of nodules are illustrated but it is understood the illustrated pattern repeats circumferentially around the cylindrical base.

FIG. 26 is a plan view of a brush over a substrate according to an embodiment of the invention where the nodule density is increased toward the edges of the substrate and the ends of the brush, for drawing simplicity, only two axial rows of nodules is illustrated but it is understood the illustrated pattern repeats circumferentially around the cylindrical base.

### DETAILED DESCRIPTION

While various compositions and methods are described, it is to be understood that this invention is not limited to the particular compositions, designs, methodologies or protocols described, as these may vary. It is also to be understood that the terminology used in the description is for the purpose of describing the particular versions or embodiments only, and is not intended to limit the scope of the present invention which will be limited only by the appended claims. The term protrusion and the term nodule can be used interchangeably to describe features of the post-CMP cleaning brushes described herein as would be known to one skilled in the art. Substrate herein is a wafer or other substrates such as flat panels, solar cell panels or the like.

Nodules according to embodiments of the invention are asymmetrical about a vertical plane normal to the page. On the cylindrical brush this translates to a plane lying on the axis of the brush and through the center of the nodule.

A prior art post-CMP cleaning brush 20 is depicted in FIG. 2. Brush 20 includes standard center nodules 22 having a circular shape as well as edge nodules 24 that include a contour or profile that corresponds to the edge of a wafer or other substrate to be cleaned. The center nodules 22 and edge nodules 24 include sharp edges 23 where flat top surfaces 27, 17 form a right angle with side surfaces 25, 15. This brush does not have a cylindrical shape from end to end.

FIGS. 2 and 2a depicts a post-CMP cleaning process as is known in the art, which includes positioning a substrate 32 between a pair of cleaning brushes 30 having a plurality of cylindrical nodules 34 positioned in axial rows around the circumference of the brushes. The substrate 32 is rotated as shown by arrow 36 and the brushes 30 are rotated in opposing directions as shown by arrows 38. Thus, as the brushes 30 are rotated the sharp edges 33 of the nodules 34 formed by the intersection between the top surface 37 and side surfaces 35 of the nodules 30 contact the substrate 32 first. These sharp edges 33 sequentially contacting the substrate 32 as the brushes 30 are rotated is not optimal for protecting and cleaning the substrate.

It is believed that the mechanical forces used to clean substrates with post-chemical mechanical planarization cleaning brushes (CMP brushes) can be better optimized with use of nodule patterns that are non uniform or non symmetrical. Asymmetric nodules, for example nodules having a curved or rounded portion where the nodules contact the substrate and a different configuration on a trailing edge that does not contact the substrate are believed to provide advantageous cleaning. Moreover, varying the density of the nodules along the axial length can compensate the different relative velocities and scrubbing time on rotating substrates that is inherent when the circular substrates rotate about a central axis. For example, the center of the substrate in FIG. 1a will be in almost constant scrubbing engage the rotating brush and the regions near the outer edge of the wafer infrequently, relatively speaking, engage the brush. In embodiments of the invention, nodules can be asymmetric about a plane extending axially through the brush and through the cylindrical base axis and can have varying densities along the axial length of the brush.

Referring to FIGS. 3-3b, a brush 40 has a cylindrical base 42 with two opposing ends 44, 46, an axis 48, an outer cylindrical surface 50, and a plurality of nodules 52 extending from the outer cylindrical surface. As best seen in FIG. 3a, each nodule is asymmetric about a plane 55 extending axially through the brush and through the brush axis 48. The brush has an intended direction of rotation as indicated by the arrow 60 and has a leading edge 62 and a trailing edge 64. The leading edge, in this embodiment, has a leading edge angle 66 defined by the outer cylindrical surface 68 of the nodule and the top surface 70. A trailing edge angle 72 is similarly defined and is greater than the leading edge. Each nodule has a central axis 74 and a point 76 of maximum elevation with respect to the cylindrical base 42 or cylindrical surface 50. The brush has two opposing axial end rows 78, 80.

Referring now to FIGS. 4a-19, there can be seen representations of a plurality of asymmetric nodule configurations according to embodiments of the present invention. FIGS. 4a, 4b, 12 depict a nodule 100, 110, according to an embodiment of the present invention having a substrate engagement surface 109, 119 including a top surface 107, 117 and a rounded leading edge 103, 113 formed where front side surface 105, 115 and top surface meet 107, 117. Top surface 107 can have a flat or rounded configuration. When nodules 100 are dispersed around a brush as described herein and rotated to clean a substrate, rounded or curved leading edges 103, 113 are the first portion of the nodules 100, 110 to contact the substrate, which reduces the potential for excessive force caused by sharp leading edges. The arrows indicate the intended direction of rotation of the cylindrical bases from which the nodules extend in particular embodiments. In alternate embodiments the cylinders can be rotated oppositely.

The nodule of FIG. 4a has a leading edge 62 with a radius of curvature r1 substantially greater that the radius of curvature r2 of the trailing edge 64.

Nodule 110 can have a smaller width or circumference to height ratio than the nodule 100. This allows nodules 110 to deform more easily and therefore provide a lower mechanical force per nodule onto the substrate, reducing the likelihood of scratching the substrate. In one embodiment, a post-CMP brush employing such nodules 110 can have a greater number of nodules 110 than a brush with thicker nodules 110.

FIGS. 6 and 11 depict a nodule 120 according to a further embodiment of the present invention. Essentially a cylindrical or tapered cylindrical base and with a dome 121.1 having a cutout portion 128. Nodule 120 has a curved or rounded substrate engagement surface 129 extending from front side surface 125 along leading edge 123 and top surface 127. Nodule 120 also includes a step 124 and a stepped trailing or rear surface 126. Stepped nodules 120 provide a thinner substrate engagement portion 122, similar to nodule 110, that will deform more easily to reduce the likelihood of damage to the substrate. The stepped rear surface 126 provides a wider base portion 121, however, which provides for a stronger base that prevents the nodule 120 from deforming too easily and not applying enough force to clean a substrate. The engagement portion 122 can have a variable width, the width of these portions can be chosen to supply appropriate force to the substrate.

FIGS. 7, 8, 18, 9, and 19 depict nodules according to embodiments of the present invention. FIGS. 7, 8, 9, and 19 depict a nodules 130, 140, 150 having a sharp corner 131, 141, 151, 151.1 as a leading edges and a curved or rounded trailing edge 133, 143, 153 of a substrate engagement surfaces 139, 149, 159 on a back side 136, 146, 156 of the nodules 130, 140, 150. In other embodiments the direction of rotation may be reversed.

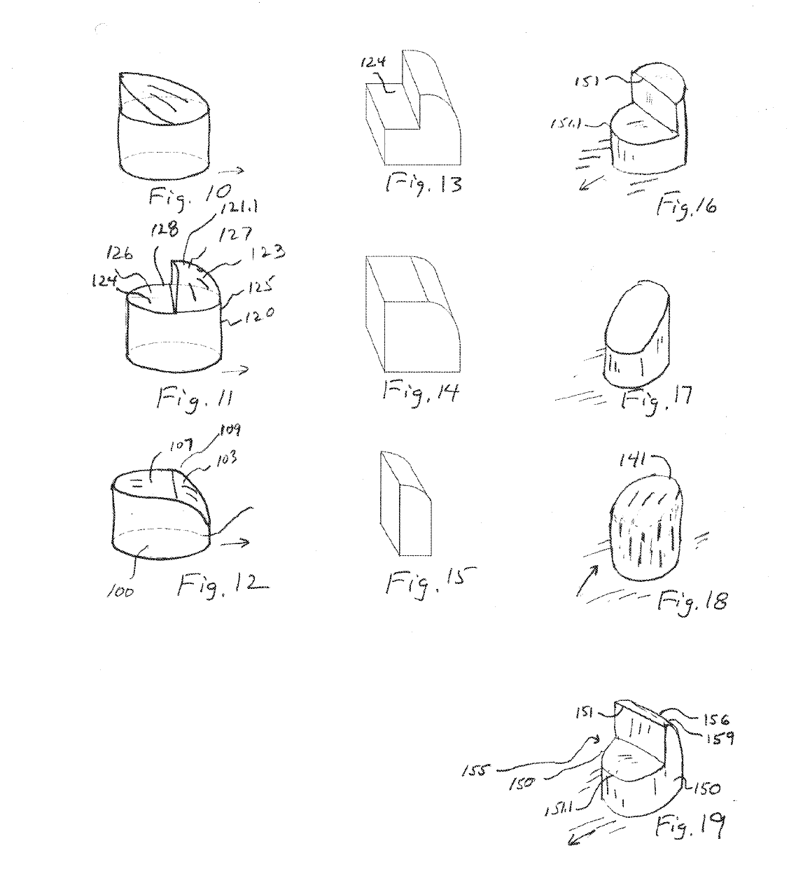

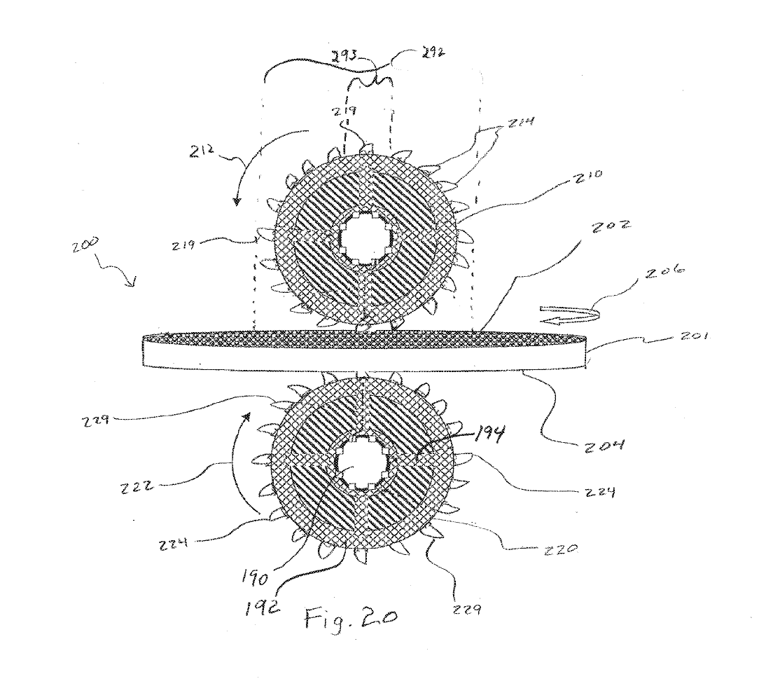

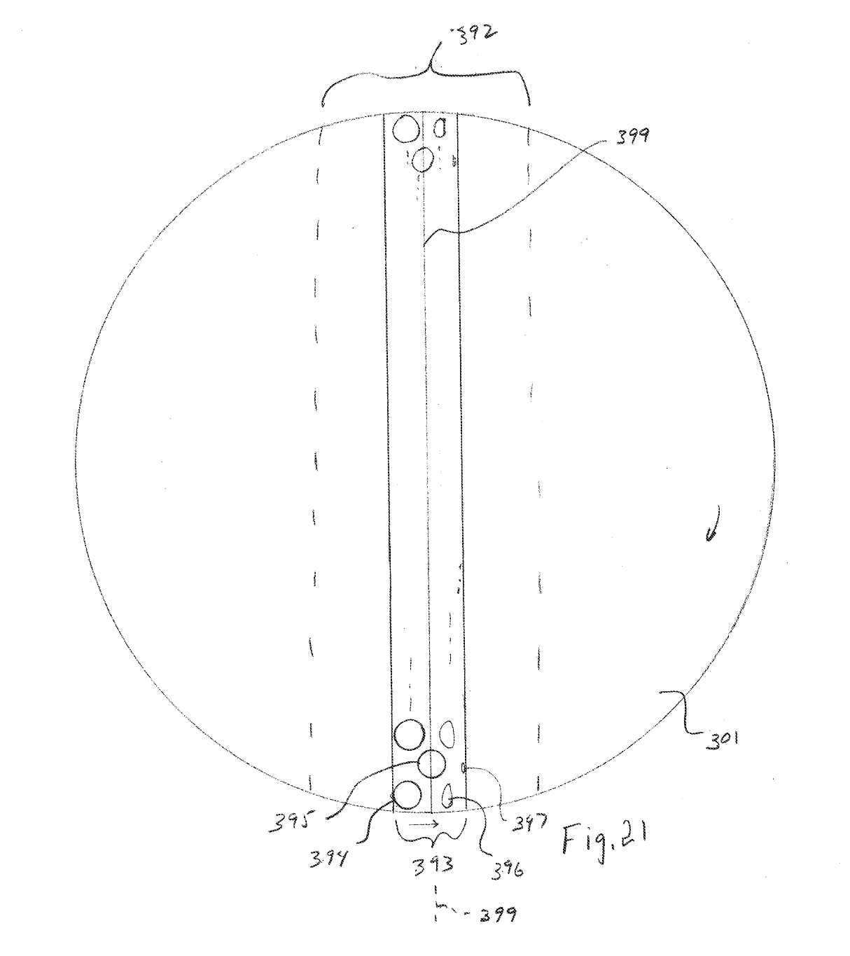

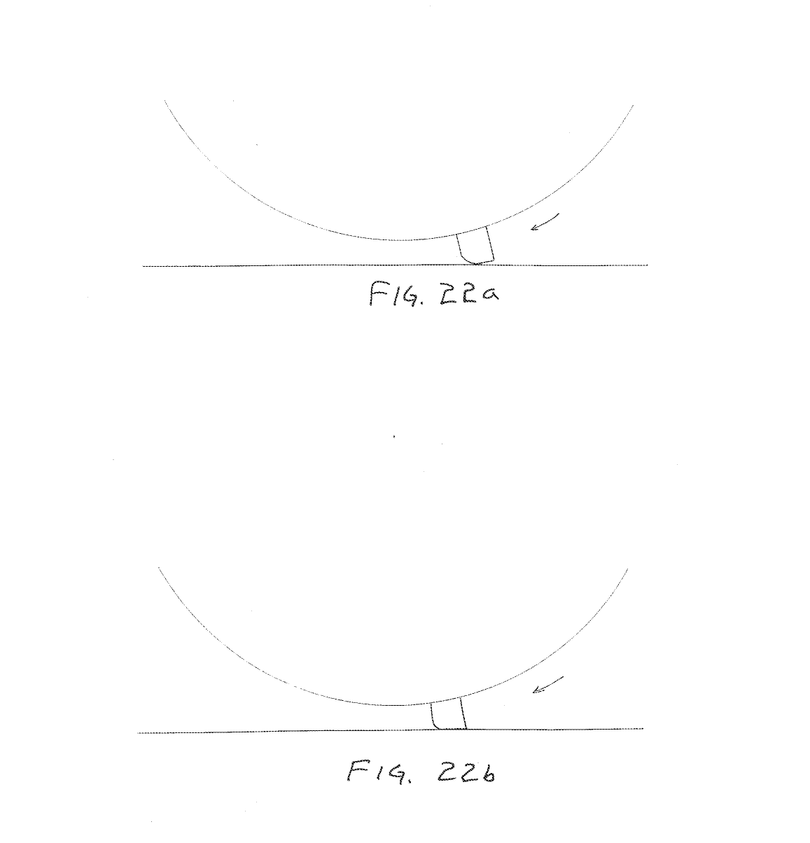

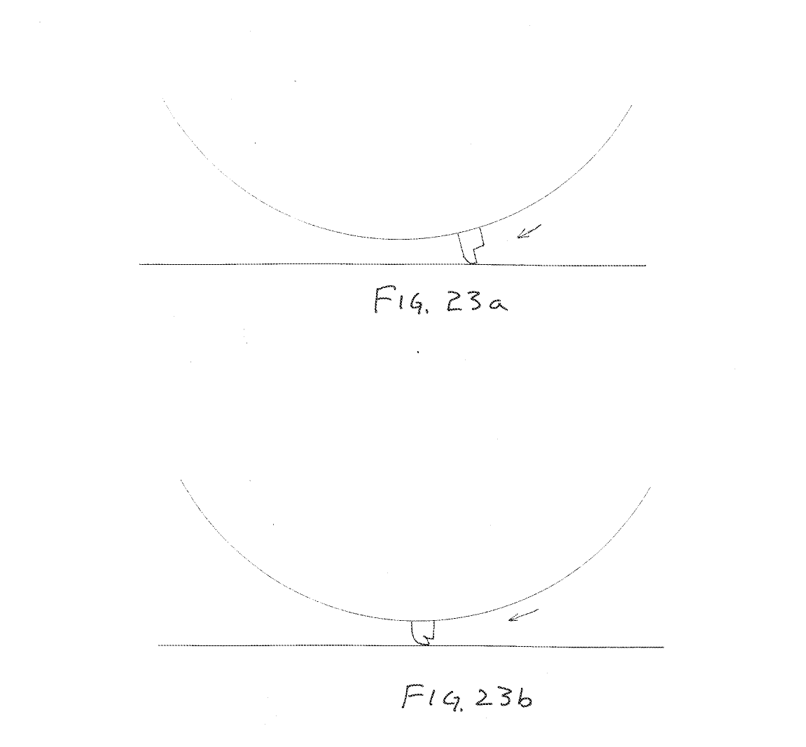

FIGS. 8 and 18 depict a nodule 140 having a leading sharp edge 141, a curved or rounded substrate engagement surface 149 extending from a back side 146 of nodule 140 all the way to front side 145 of nodule 140. FIGS. 9 and 19 depict a nodule 150 having a stepped initial engagement portion 155 curved or rounded surface 159 on a back side 156 of the nodule 150 and a stepped front surface 155. Although nodules are depicted as having a circular base or footprint, nodules can have various other configurations, such as square or rectangular as shown in FIGS. 10A-10F, ovate, triangular or other shape.

FIG. 20 depicts a system 200 for carrying out a post-CMP cleaning process on a substrate 201 according to an embodiment of the present invention including a first or top post-CMP 210 brush and a second or bottom post-CMP brush 220. Each brush has a fluid flow cavity 190, a porous cylindrical base 192 and flow conduits 194 extending from the fluid flow cavity to the porous cylindrical base. The flow conduits, in this embodiment have porous foam unitary with the porous foam of the cylindrical base and the nodules. First brush 210 engages a top or front side 202 of the substrate 201 and second brush 220 engages a bottom or back side 204 of the substrate 201 as the substrate 201 rotates in the direction indicated by 206. First brush 210 rotates in direction 212 and has a plurality of asymmetric nodules 214 aligned in axial rows around the circumference of brush 210. Second brush 220 rotates in the opposite direction 222 and has a plurality of asymmetric nodules 224 aligned in axial rows around the circumference of brush 220. Therefore, both brushes are rotating towards the rotating substrate. Each set of nodules 214, 224 is configured such that the curved or rounded substrate engagement surface 219, 229 of the nodules 214, 224 comprises the leading portion of the nodules that will contact the substrate 201 first. In some embodiments, only one of top brush 210 or bottom brush 220 includes asymmetric nodules and the other can utilize standard symmetric nodules (for example with rounded engagement surfaces.)

As can be seen most clearly with reference to FIG. 1A when a rotating brush is used to clean a rotating substrate, the central portion of the substrate will have more frequent contact with the brush than the edge regions of the substrate as the substrate is rotated, due to the edge regions having to rotate a greater distance to reach the opposing sides of the brush. As such, employing nodules having the same amount of contact area throughout the length of the brush can lead to one of two undesirable results. If the center region of the substrate is adequately cleaned, the edge region of the substrate may not be adequately cleaned due to the decreased contact with the brush. However, if the edge region is adequately cleaned, the center region may be damaged due to excess contact and friction with the brush due to the increased contact with the brush.

FIGS. 21 and 24a-24e illustrate the profile 392 of the brush 310 on the substrate 312 and the actual region 393 of brush/substrate contact. Note that due to the shape and angle of the top surface of the nodules, the initial engagement of the nodule is substantially the entire top surface of the nodule represented by the larger contact circular area 394. As the brush rotates the contact region stays large through the central line 399 of the contact region 393. The contact region 396 then diminishes rapidly as the brush rotates further and just before disengaging is quite small. The brush/substrate engagement region 393 is not fixed on either the brush or substrate as they are both rotating but it will be a static region below or adjacent to the brush, depending on the brush substrate orientation.

Referring to FIG. 25, the brushes 410 can be provided with nodules having a smaller footprint and contact surfaces at the center region 412 of the brush proximate the axial center c that engages the central region 414 of the substrate to reduce the contact between the nodules and the central region of the substrate and nodules towards the outer regions of the brush that engage the outer regions 416 of the rotating substrate, can be wider-larger diameter and have larger contact surfaces than in the central region, such as the axial center c. Such a distribution can allow for more uniform contact of the brush across the substrate, which results in optimum cleaning of substrate edge regions while minimizing the potential for damage to the central region of the substrate by excessive brush to substrate contact. This distribution is the variation in the area density and is a gradient. Each nodule has a footprint, where it connects to the cylindrical base, and has a foot print area. The area density is defined by the cumulative foot print areas of a particular region divided by the respective cylindrical area of the particular region. The area density may change more than 30% in some embodiments comparing the central region of the brush and the outer axial regions. In some embodiments, more than 50%. These area densities are appropriately taken intermediate the opposing outside rows 417, 418.

Referring to FIG. 26, the brush 510 can be provided with a lower density of nodules providing less contact surfaces at the central region 514 of the substrate compared to outer regions 516 to reduce the contact at the central region compared to the outer regions. Such a distribution can allow for more uniform contact of the brush across the substrate, which results in optimum cleaning of substrate edge regions while minimizing the potential for damage to the central region of the substrate. The distribution is a gradient reflected by the varying numeric density of the cylindrical base intermediate the opposing end rows. The numerical density of the nodules, defined as the number of nodules per cylindrical unit area of the cylindrical base. As shown the numerical density varies axially along the brush from one of the two opposing end rows 517 to the other of the two opposing end rows 518. Higher density at the ends, where the substrate will infrequently engage the brush, and lower density in the middle, at the axial center c, where the substrate frequently engages the brush is illustrated.

In another embodiment, central region can utilized step reduction nodules and edge region can utilize full size nodules. Although described as utilizing asymmetric nodules, brush can also employ symmetric nodules, such as nodules having rounded or planar top surfaces. In another embodiment, both the density of nodules and the size of nodules can vary depending on the position on the brush. Due to the axial outer rows in some cases being of a different shape and sized due to the engagement of the edge of the substrate, the variation of the shapes and sizes of the nodules varying axially is in certain embodiments appropriately considered from laterally inside of said outer axial row(s).

In some embodiments, the brush can have the density of the nodules varying along the axial length as well as having the individual nodule surface engagement area also varying along the axial length. Due to the axial outer rows in some cases being of a different shape and sized due to the engagement of the edge of the substrate, the density of the nodules varying axially is in embodiments appropriately considered from laterally inside of said outer opposing axial end rows.

In some embodiments the density and/or porosity of the foam can vary such as at the nodules. For example, the nodules can have a greater porosity at their outwardly exposed surfaces than at cylindrical surfaces extending from the base.

In some embodiments, the fact that the substrate is rotating in the same direction as the brush on one half of the brush and on the other half of the brush is rotating in the opposite direction as the substrate, providing different relative engagement velocity ranges, is taken into consideration in the size, characteristics, density, of the nodules on the respective halves of the brush. For example the half of the brush rotating with the substrate could have a larger range of nodules to provide slightly greater scrubbing action as compared to the half of the brush rotating against the nodule.

Prior art patents disclose specific configurations, formulations, structures, systems, processes, and solutions that are suitable for use with the various invention embodiments disclosed herein. Particular patents and publications that are incorporated by reference herein are U.S. Pat. Nos. 7,984,526; 6,299,698; 6,240,588; 5,875,507; 4,083,906; 5,311,634; and 5,554,659; 5,675,856; and U.S. Patent Publication No. 2009-0044830 A1, International Publication No. WO 2011/103538.

While several exemplary articles, compositions, apparatus, method embodying aspects of the present invention have been shown, it will be understood, of course, that the invention is not limited to these embodiments. Modification may be made by those skilled in the art, particularly in light of the foregoing teachings. For example, components and features of one embodiment may be substituted for corresponding components and features of another embodiment. Further, the invention may include various aspects of these embodiments in any combination or sub-combination.

1. A brush for cleaning of substrates following chemical mechanical polishing of the substrates, the brush having a cylindrical base having an axis with a pair of ends, the cylindrical shape extending from end to end, and a plurality of nodules extending from the cylindrical base and being unitary therewith, the brush having an intended direction of rotation whereby each nodule has a forward side and a rearward side, the cylindrical base and nodules comprising a unitary porous foam structure, the plurality of the nodules each having a shape that is asymmetrical with respect to a radially and axially extending plane extending centrally through each respective nodule and through the axis of the cylindrical base.

2. The brush for cleaning of substrates following chemical mechanical polishing of the substrates of claim 1 wherein each of the plurality of nodules has a curved leading edge oriented towards the intended direction of rotation and an opposite trailing edge and wherein the trailing edge has a minimum radius of curvature and the leading edge has a minimum radius of curvature and the minimum curvature of the trailing edge is less than that of the minimum curvature of the leading edge.

3. The brush for cleaning of substrates following chemical mechanical polishing of the substrates of claim 1 wherein each nodule has a step whereby there are two outwardly facing surfaces.

4. The brush for cleaning of substrates following chemical mechanical polishing of the substrates of claim 1 wherein each of the plurality of nodules has a base with one of a circular footprint or a elliptical footprint.

5. The brush for cleaning of substrates following chemical mechanical polishing of the substrates of claim 1, wherein each of the nodules has an axis and each of said nodules has a flat upper surface portion, and said flat upper surface portion is at an oblique angle with respect to the axis of the each respective nodule.

6. The brush for cleaning of substrates following chemical mechanical polishing of the substrates of claim 1, wherein each of the nodules has a central axis and further has a curved upper surface portion with a point of maximum elevation with respect to the cylindrical base, and wherein said point of maximum elevation is displaced from said central axis.

7. The brush for cleaning of substrates following chemical mechanical polishing of the substrates of claim 6, wherein each of the nodules has an axis and further has a flat upper surface portion.

8. The brush for cleaning of substrates following chemical mechanical polishing of the substrates of claim 1 wherein the plurality of nodules on the cylindrical base have opposing end rows and wherein each cylindrical unit area of the cylindrical base intermediate the opposing end rows have a numerical density of the nodules, defined as the number of nodules per cylindrical unit area of the cylindrical base, and wherein the numerical density varies from an axial center of the brush to each of the ends.

9. The brush for cleaning of substrates following chemical mechanical polishing of the substrates of claim 1 wherein the plurality of nodules on the cylindrical base have two opposing end rows, wherein each nodule has a footprint and a footprint area, and wherein each cylindrical unit area of the cylindrical base intermediate the opposing end rows have an area density of the nodules, defined as the cumulative footprint area of the nodules in a particular cylindrical surface area of the cylindrical base divided by said cylindrical surface area, and wherein the area density of the nodules varies from an axial center of the brush to each of the ends.

10. A brush for cleaning of substrates following chemical mechanical polishing of the substrates, the brush having a cylindrical base having an axis with a pair of ends, the cylindrical shape extending from end to end, and a plurality of nodules extending from the cylindrical base and being unitary therewith, the plurality of nodules having opposing axial end rows, the brush having an intended direction of rotation whereby each nodule has a forward side and a rearward side, the cylindrical base and nodules comprising a unitary porous foam structure, wherein at least one of the size of the nodules or the spacing of the nodules on the cylindrical base has gradient extending axially on the cylindrical base intermediate the two opposing end TOWS.

11. The brush for cleaning of substrates following chemical mechanical polishing of the substrates of claim 10 wherein the nodules have at least three different configurations, said different configuration being at least one of size and shape.

12. The brush for cleaning of substrates following chemical mechanical polishing of the substrates of claim 10 wherein the plurality of the nodules each having a shape that is asymmetrical with respect to a radially and axially extending plane extending centrally through each respective nodule and through the axis of the cylindrical base.

13. The brush for cleaning of substrates following chemical mechanical polishing of the substrates of claim 10, wherein the plurality of nodules on the cylindrical base have opposing end rows and wherein each cylindrical unit area of the cylindrical base intermediate the opposing end rows have a numerical density of the nodules, defined as the number of nodules per cylindrical unit area of the cylindrical base, and wherein the numerical density varies from an axial center of the brush to each of the ends.

14. The brush for cleaning of substrates following chemical mechanical polishing of the substrates of claim 8, wherein The brush for cleaning of substrates following chemical mechanical polishing of the substrates of claim 1 wherein the plurality of nodules on the cylindrical base have two opposing end rows, wherein each nodule has a footprint and a footprint area, and wherein each cylindrical unit area of the cylindrical base intermediate the opposing end rows have an area density of the nodules, defined as the cumulative footprint area of the nodules per cylindrical unit area of the cylindrical base, and wherein the area density of the nodules varies from an axial center of the brush to each of the ends.

15. A brush for cleaning of substrates following chemical mechanical polishing of substrates, the brush having a cylindrical base having an axis with a pair of ends, the cylindrical shape extending from end to end, and a plurality of nodules extending from the cylindrical base and being unitary therewith, the brush having an intended direction of rotation whereby each nodule has a forward side and a rearward side, the cylindrical base and nodules comprising a unitary porous foam structure, wherein the plurality of nodules on the cylindrical base have two opposing end rows and wherein each cylindrical unit area of the cylindrical base intermediate the opposing end rows have a numerical density of the nodules, defined as the number of nodules per cylindrical unit area of the cylindrical base, and wherein the numerical density varies axially along the brush from one of the two opposing end rows to the other of the two opposing end rows, there being at least four changes in said numerical density.

16. The brush of claim 15 wherein the plurality of nodules on the cylindrical base each having a shape that is asymmetrical with respect to a radially and axially extending plane extending centrally through each respective nodule and through the axis of the cylindrical base.

17. The brush for cleaning of substrates following chemical mechanical polishing of the substrates of claim 1 wherein each of the plurality of nodules has a curved leading edge oriented towards an intended direction of rotation of the brush and an opposite trailing edge and wherein the trailing edge has a minimum radius of curvature and the leading edge has a minimum radius of curvature and the minimum radius of curvature of the trailing edge is less than that of the minimum radius of curvature of the leading edge.

18. A brush for cleaning of substrates following chemical mechanical polishing of substrates, the brush having a cylindrical base having an axis with a pair of ends, the cylindrical shape extending from end to end, and a plurality of nodules extending from the cylindrical base and being unitary therewith, the brush having an intended direction of rotation whereby each nodule has a forward side and a rearward side, the cylindrical base and nodules comprising a unitary porous foam structure, each of the plurality of nodules having a footprint and a footprint area, and wherein the plurality of nodules on the cylindrical base have two opposing end rows and wherein each cylindrical unit area of the cylindrical base intermediate the opposing end rows have an area density of the nodules, defined as the cumulative footprint area of nodules per cylindrical unit area of the cylindrical base, and wherein the area density varies axially along the brush from axially interior one of the two opposing end rows to axially interior the other of the two opposing end rows.

19. The brush of claim 18 wherein the plurality of nodules on the cylindrical base each having a shape that is asymmetrical with respect to a radially and axially extending plane extending centrally through each respective nodule and through an axis of the cylindrical base.

20. The brush for cleaning of substrates following chemical mechanical polishing of the substrates of claim 18 wherein each of the plurality of nodules has a curved leading edge oriented towards the intended direction of rotation of the brush and an opposite trailing edge and wherein the trailing edge has a minimum radius of curvature and the leading edge has a minimum radius of curvature and the minimum radius of curvature of the trailing edge is less than that of the minimum radius of curvature of the leading edge.
